(19) United States
(12) Patent Application Publication
(10) Pub. No.: US 2019/0088598 A1
(43) Pub. Date: Mar. 21, 2019

(54) METHOD FOR FORMING THROUGH SUBSTRATE VIAS IN A TRENCH

(71) Applicant: Innovative Micro Technology, Goleta, CA (US)

(72) Inventors: Christopher S. GUDEMAN, Lompoc, CA (US); Jamie Yao, Santa Barbara, CA (US)

(73) Assignee: Innovative Micro Technology

(21) Appl. No.: 15/710,969

(22) Filed: Sep. 21, 2017

(51) Int. Cl. H01L 23/535; H01L 21/768

(52) U.S. Cl. CPC H01L 23/535; H01L 21/76829; H01L 21/76865; H01L 21/76871; H01L 21/76898

(57) ABSTRACT

A device and method for forming through silicon vias (TSVs) in a composite substrate is disclosed. The through substrate via may include an embedded insulating etch stop layer sandwiched between a first and a second substrate layers. The via may include at least one hole formed in the first substrate layer down to the embedded insulating etch stop layer, an insulator formed onto the walls of the at least one hole, a conductive material disposed in the at least one hole, a trench etched into the second substrate layer on the obverse side of the composite substrate through the second substrate material and through the embedded insulating etch stop layer, directly opposite the at least one hole, and a first metal pad formed over the at least one hole and at the bottom of the trench.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to integrated circuit and microelectromechanical systems (MEMS) devices. More particularly, this invention relates to the formation of vias in wafers on which the integrated circuits and MEMS devices may be fabricated.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer, in order to encapsulate the device in a hermetic cavity.

In order to control such a microfabricated switch, electrical access must be provided that allows power and signals to be transmitted to and from the encapsulated switch. Vias are typically formed in at least one of the wafers to provide this access. If the device is for high frequency signals, it may also be important to design the vias such that their electrical effects on the signals are minimized or at least known and understood.

Accordingly, electrical vias allow electrical access to integrated circuit (IC) electronic devices or microelectromechanical systems (MEMS) within a package or in a circuit.

Long, narrow vias are often created by plating a conductive material into a hole formed in a substrate. A hole may be created in a substrate by a directional material removal process such as reactive ion etching (RIE). A seed layer may then be deposited conformally over the etched surface, to provide a conductive layer to attract the plating material from the plating bath.

In some applications, a device for example, a MEMS switch needs to be hermetically sealed in order to maintain performance and reliability. This may require sealing the device in a hermetic cavity which may be formed between a lid wafer and a device wafer. In this case, a method needs to be used to gain electrical access to the enclosed device, using through substrate vias. Because of the need to encapsulate the devices with a lid wafer relieved in trenched areas to provide clearance for the devices, it is often desirable to have vias located in trenches. Having a device disposed in a trench also allows the vias under it to be shorter, therefore the resistance of the vias is less which is a desirable property for some applications.

Therefore, a need exists for a methodology which can form vias in variety of material substrates, which can be fabricated in trenched regions of the wafer. These methods may need to be applied to a hermetically encapsulated MEMS device.

### SUMMARY

A method is described which can be used to make conductive vias in a silicon substrate and located at the bottom of a trench. The method may be used with relatively high resistivity substrate materials, such as lightly doped silicon, but the via formed may nonetheless have excellent conductivity. The method may be particularly suitable for high frequency RF devices which need a relatively insulating substrate to minimize capacitive coupling losses. The method may be used to form vias which extend through substrates which are many hundreds of microns thick.

The method may be used to make through substrate vias in a substrate with a trench formed therein. The trench may be necessary to accommodate a device such as a MEMS device that was manufactured on a substrate. The clearance for the MEMS device may be provided by the trench. The substrate may have an etch stop layer embedded therein. The etch stop layer may provide a convenient mechanism for forming the through substrate via (TSV) in the trench, as is described in detail below.

A feature of this process is that a hole may first be made in a suitable substrate. The hole may be formed in a first side of the substrate. In some embodiments, the hole may be an annulus, forming a post of substrate material surrounded by the annular void. The annular void may extend partially through the thickness of the substrate or entirely through.

In other embodiments, the void is a hole rather than an annulus. The hole may be a through hole or a blind hole. After formation, the hole may be subsequently lined with an insulating material, and then filled with a conductive material. Accordingly, the hole may be filled with a preferred metal material, for example, gold or copper having higher conductivity than the original substrate material, silicon for example. If the conductive material is plated, the surface may subsequently be planarized.

In some embodiments, to form the insulating material, the walls of the hole as well as other exposed surfaces may be oxidized. The oxide may then be removed from the top surface of the substrate material. A metal pattern may then be formed over the exposed top surface of the conductive material. The opposite side substrate material may then be removed to expose the blind hole or annular void now filled with oxide material.

Remaining process steps may also be performed at this point, to complete fabrication of the device. The remaining steps may include formation of the trench by etching a frontside of the substrate down to the embedded etch stop (silicon dioxide, e.g. layer). Other steps may be the formation and patterning of an insulating layer on the surface of the substrate, and patterning of another conductive layer over the insulator.

In one embodiment, the substrate is a silicon-on-insulator (SOI) substrate with a thin device layer, a buried oxide layer, and a thicker handle layer. The buried oxide layer may provide the embedded etch stop layer. The annulus may be formed through the thickness of the device layer, extending to the buried oxide. The handle layer may now be removed to complete the opposite side processing. In another embodiment, a regular, monolithic silicon substrate may be used. In this case, the annulus may be formed as a blind hole partially through the substrate from the first side. The opposite side may subsequently be ground or etched away.

The trench may then be formed by etching away the substrate material on the obverse side of the substrate, down to the buried oxide etch stop layer.

Numerous devices can make use of the systems and methods disclosed herein. In particular, RF switches benefit from the reduced capacitive coupling that a relatively insulative substrate surrounding the high conductivity vias can provide. High density vias formed in the relatively insulative substrate increase the density of devices which can be formed on a substrate, thereby reducing cost to manufacture. The performance of such devices may also be improved, in terms of insertion loss, distortion and isolation figures of merit.

Accordingly, a through substrate via may be formed in a composite substrate. The composite substrate may have an embedded insulating etch stop layer sandwiched between a first and a second substrate layers. The through substrate via may include at least one hole formed in the first substrate layer down to the embedded insulating etch stop layer, an insulator formed onto the walls of the at least one hole, a conductive material disposed in the at least one hole, a trench etched into the second substrate layer on the obverse side of the composite substrate through the second substrate material and through the embedded insulating etch stop layer, directly opposite the at least one hole, and a first metal pad formed over the at least one hole and at the bottom of the trench.

These and other features and advantages are described in, or are apparent from, the following detailed description.

### BRIEF DESCRIPTION OF THE DRAWINGS

Various exemplary details are described with reference to the following figures, wherein:

FIG. 1a is a cross sectional view of a silicon substrate with an annulus formed therein; FIG. 1b is a perspective view of a silicon substrate with an annulus formed therein;

FIG. 2a is a cross sectional view of a silicon substrate with an oxide formed over the substrate and annulus and then patterned and etched to remove material over the annulus; FIG. 2b is a perspective view of a silicon substrate with an oxide formed over the substrate and annulus and then patterned and etched to remove material over the annulus;

FIG. 3a is a cross sectional view of a silicon substrate with a metal pattern formed over the oxide and annulus; FIG. 3b is a perspective view of a silicon substrate with the metal pattern formed over the oxide and annulus;

FIG. 4a is a cross sectional view of a silicon substrate with the annulus and metal pattern, and with handle layer removed; FIG. 4b is a perspective view of a silicon substrate with the annulus and metal pattern, and with handle layer removed;

FIG. 5a is a cross sectional view of a silicon substrate with the silicon post removed from the annulus, leaving a via void; FIG. 5b is a perspective view of a silicon substrate with the silicon post removed from the annulus, leaving a via void;

FIG. 6a is a cross sectional view of a silicon substrate with the via void filled with a conductive material; FIG. 6b is a perspective view of a silicon substrate with the via void filled with a conductive material;

FIG. 7a is a cross sectional view of a first step in a process for forming the through substrate silicon via at the bottom of a trench; FIG. 7b is a cross sectional view of a first step in a process for forming the through substrate conductive material via at the bottom of a trench;

FIG. 8a is a cross sectional view of a second step in a process for forming the through substrate silicon via at the bottom of a trench; FIG. 8b is a cross sectional view of a second step in a process for forming the through substrate conductive material via at the bottom of a trench;

FIG. 9 is a cross sectional view of a third step in a process for forming the through substrate via at the bottom of a trench;

FIG. 10 is a cross sectional view of a fourth step in a process for forming the through substrate via at the bottom of a trench

FIG. 11 is a cross sectional view of a next step in a process for forming the through substrate via at the bottom of a trench;

FIG. 12 is a cross sectional view of a next step in a process for forming the through substrate via at the bottom of a trench;

FIG. 13 is a cross sectional view of a next step in a process for forming the through substrate via at the bottom of a trench

FIG. 14 is a cross sectional view of a next step in a process for forming the through substrate via at the bottom of a trench;

FIG. 15 is a cross sectional view of a silicon substrate with a first via formed therein, the first via disposed at the bottom of a trench;

FIG. 16 is a cross sectional view of a silicon substrate with a second via formed therein, the first via disposed at the bottom of a trench and the second through the entire thickness of the substrate;

FIG. 17 is a cross sectional view of a silicon substrate with a first metallic via formed therein, the first metallic via disposed at the bottom of a trench;

FIG. 18 is a cross sectional view of a silicon substrate with a second metallic via formed therein, the first metallic via disposed at the bottom of a trench and the second through the entire thickness of the substrate.

FIG. 19a is a plan view of a substrate with a blind annulus formed therein; FIG. 19b is a cross sectional view of the blind annulus; FIG. 19c is a cross sectional view of the back side of the substrate removed to reveal the conductive material in the blind annulus.

FIG. 20a is a plan view of a substrate with a blind annulus formed therein, the annulus filled with a conductive material; FIG. 20b is a cross sectional view of the blind annulus; and FIG. 20c is a cross sectional view of the back side of the substrate removed to reveal the conductive material in the blind annulus;

FIG. 21 is an exemplary flowchart illustrating a first method of forming a through substrate via in a trench; and

FIG. 22 is an exemplary flowchart illustrating a second method of forming a through substrate via in a trench.

### DETAILED DESCRIPTION

The systems and methods described herein may be particularly applicable to microelectromechanical devices, wherein the vias may be required to be very low loss or when the device is small. MEMS devices are often fabricated on a composite silicon-on-insulator wafer, consisting of a relatively thick (about 675 μm) “handle” layer of silicon overcoated with a thin (about 1 μm) layer of silicon dioxide, and covered with a silicon “device” layer. The MEMS device may be made by forming moveable features in the device layer by, for example, deep reactive ion etching (DRIE) with the silicon dioxide layer forming a convenient etch stop. The movable feature is then freed by, for example, wet etching the silicon dioxide layer from beneath the moveable feature.

Alternately, MEMS devices can be fabricated on a thin silicon wafer by depositing and etching thin solid layers of metals and non-metals. If one of these layers is a sacrificial layer, the MEMS device can be released by etching this sacrificial layer, thus freeing the device or feature to move. The moveable features may then be hermetically encapsulated in a cap or lid wafer, which is bonded or otherwise adhered to the top of the silicon device layer, to protect the moveable features from damage from handling and/or to seal a particular gas in the device as a preferred environment for operation of the MEMS device.

The exemplary embodiment below is described with respect to an SOI substrate 100. The terms “first side” and “opposite side” are used herein to denote two generally parallel substrate surfaces, such as, for example, a top surface and a bottom surface of the SOI substrate. Alternative terms frequently used in the art are front side or frontside and back side or backside. Generally, the front side may have the smaller structural or functional features, and is often enclosed with a lid or other encapsulation. The backside often forms the outside of the package and may have electrical leads or vias formed therein. Accordingly, as used herein, the first side may be either the frontside or the backside, and the opposite side may be the obverse, parallel side. In one exemplary embodiment, the first side may be the device layer of an SOI substrate and the opposite side may be the handle layer. In another exemplary embodiment, the first side may be the handle layer and the opposite side the device layer. In either case, the opposite side is the obverse face of the substrate.

However, it should be understood that the systems and methods may be applied as well to a unitary silicon substrate. In this case, there is no handle layer, but the process steps are applied as described to the first side and opposite side of the unitary silicon substrate 100. Thus in this case as well, the method may be used to form a via which extends through the thickness of the silicon substrate, forming a through silicon via (TSV).

Through-hole vias are particularly convenient for MEMS devices, because they may allow electrical access to the encapsulated devices. Without such through holes, electrical access to the MEMS device may have to be gained by electrical leads routed under the capping wafer which is then hermetically sealed. It may be problematic, however, to achieve a hermetic seal over terrain that includes the electrical leads unless more complex and expensive processing steps are employed. This approach also makes radio-frequency applications of the device limited, as electromagnetic coupling will occur from the metallic bondline residing over the normally oriented leads. Alternatively, the electrical access may be achieved with through-wafer vias formed through the handle wafer, using the systems and methods described here.

The systems and methods described herein may be particularly applicable to vacuum encapsulated microelectromechanical (MEMS) devices, such as a MEMS actuator, switch, sensor, or infrared microdevice. However, they may also be applicable to any integrated circuit formed on a device wafer and encapsulated with a lid wafer. Examples of devices to which these techniques may be applicable can be found in, for example, U.S. Pat. No. 7,528,691 issued May 5, 2009, U.S. Pat. No. 7,893,798, issued Feb. 22, 2011, and U.S. Pat. No. 7,864,006, issued Jan. 4, 2011. Each of these patents is incorporated by reference in their entireties.

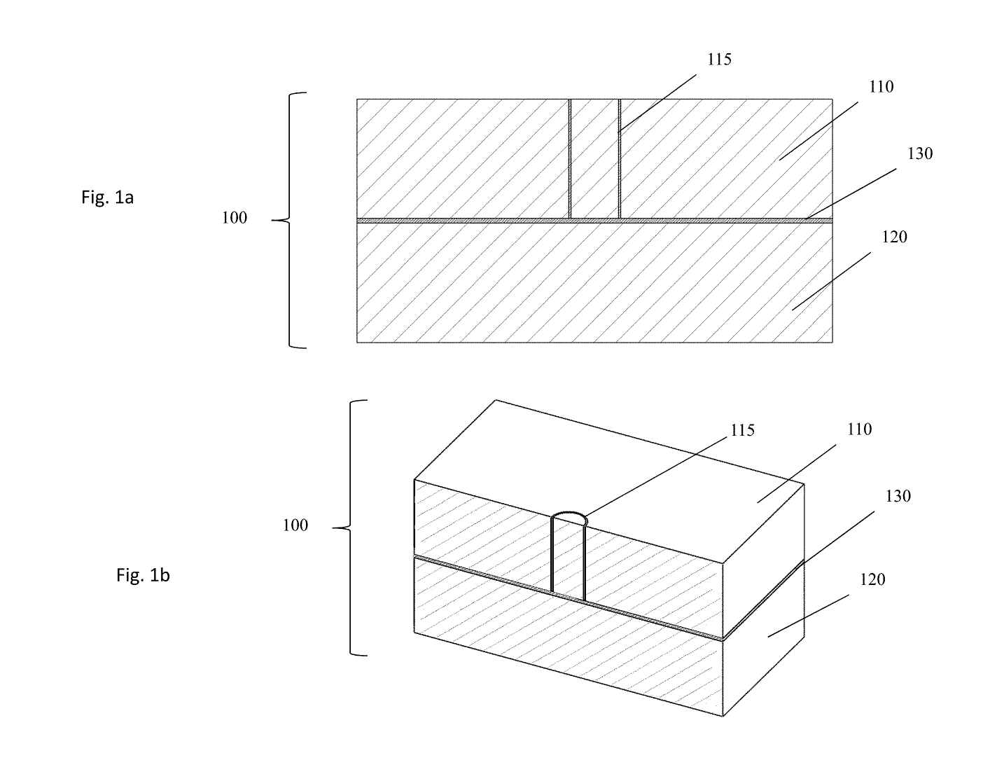

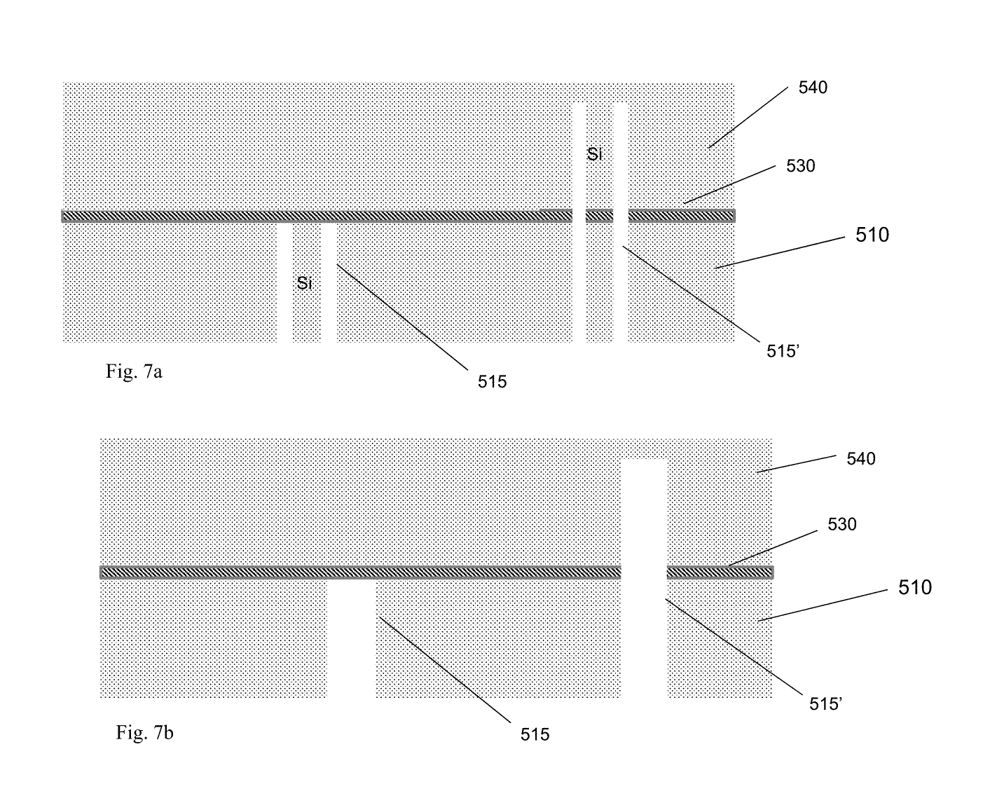

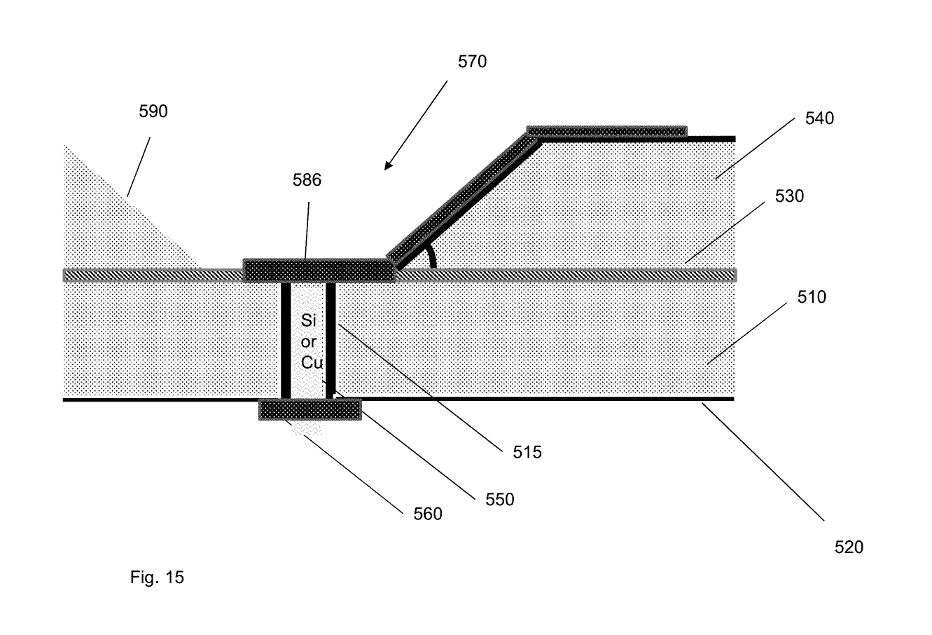

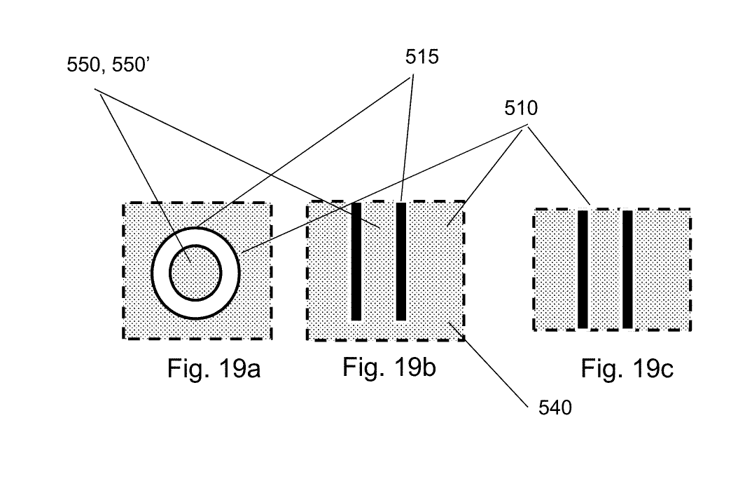

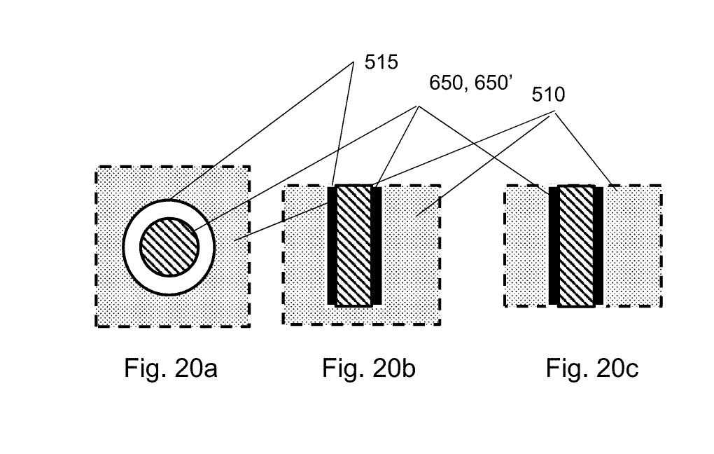

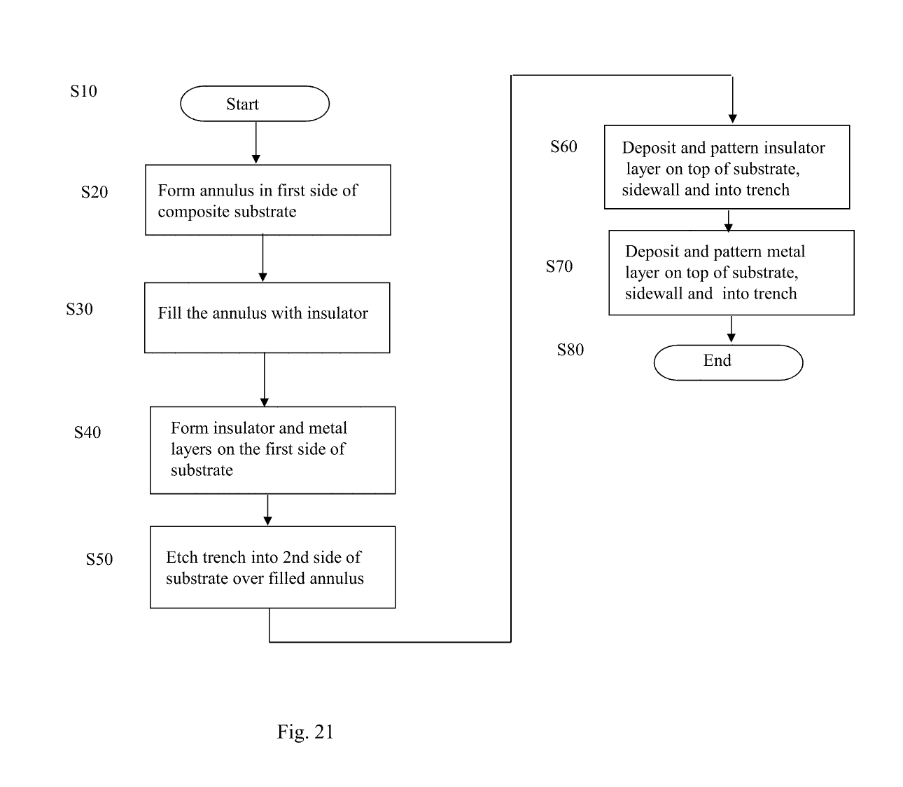

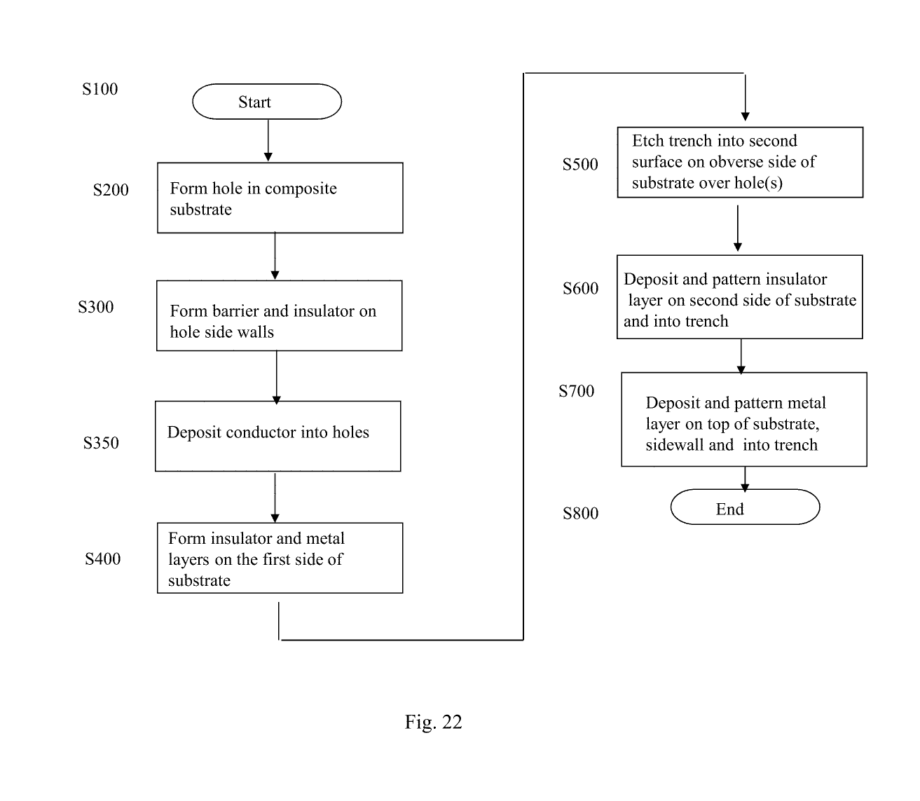

This specification is organized as follows. A first exemplary embodiment is illustrated in FIGS. 1-6. Steps of a process flow for forming the via at the bottom of a trench is shown in FIGS. 7-14. Cross sectional views of the finished vias at the bottom of trenches are shown in FIGS. 15-18. Plan views and simplified cross sectional views are shown in FIGS. 19 and 20. Two flowcharts of exemplary methods for forming the vias at the bottom of trenches are given in FIGS. 21 and 22.

FIG. 1 is a diagram of an exemplary silicon-on-insulator (SOI) substrate 100, having a device layer 110, a buried oxide layer 130 and a handle layer 120. Shown in FIG. 1a is the cross sectional view; FIG. 1b shows the perspective view of the through substrate via (TSV).

SOI wafers may come with a variety of dimensions, including some having a very thin device layer 110 on the order of 10 microns or less, typically used for integrated circuit fabrication. Other varieties may have a thin handle layer 120 on the order of 5 microns or less. An exemplary SOI wafer used for MEMS fabrication may have a device layer 110 about 250 microns thick and a handle layer about 450 microns thick, and a buried oxide on the order 3-5 microns thick. Such an SOI wafer may be appropriate for this process.

The device layer 110 may be single crystal or polycrystalline silicon of a thickness of, for example, 150 microns. The buried oxide 130 may be SiO₂ of a thickness of about 1-10 microns. The thickness of handle layer 120 may be chosen for convenience and may be several hundred microns thick, and may be polycrystalline silicon.

In the first step of the process, an annulus 115 is etched into a first side of the SOI substrate, here the silicon device layer 110. The annulus 115 may be formed down to the buried oxide 130, using Deep Reactive Ion Etching (DRIE) a technique well known in the industry. DRIE is capable of making holes or trenches with an aspect ratio of at least about 10 and at most about 50. Therefore, an annulus having dimensions of 10 microns in a 150 micron device layer is well within the capabilities of the technique. The diameter of the annulus will determine the width of the via, and may be chosen with this in mind. In the embodiment described here, the annulus may have any width from about 5 to about 100 microns. In a particular embodiment, the annulus, or more specifically, the post formed by the annulus 115, may have a diameter of about 50-75 microns, and the width between the walls of the annulus have a dimension of less than about 5 microns. That is, the trench of the annulus may have a width of less than about 5 microns and a depth of several hundred microns, for an aspect ratio of around 33. Most typically, the width of the trench may be about 3 microns and the depth about 100 microns. Reference number 115 should be understood to refer either to the annulus or to the post defined by the annulus.

Accordingly, forming the annulus 115 comprises forming the annulus to a depth that is less than the thickness of the substrate material, such that the annulus is a blind hole. The annulus 115 may be formed using deep reactive ion etching, forming a trench with an aspect ratio of at least 10 and no more than about 50.

When the silicon substrate is a silicon-on-insulator (SOI) substrate 100, the annulus 115 may be formed in the front side of the SOI substrate, which may be the device layer 110 of the silicon-on-insulator substrate. Accordingly, for an SOI substrate, forming the annulus may comprise forming the annulus to a depth that is a thickness of the device layer of the silicon-on-insulator substrate, such that the annulus extends completely through the device layer. For other substrates such as a unitary silicon substrate, the annulus may be formed as a blind trench into the first side of the silicon substrate. The annulus 115 is shown in cross section in FIG. 1a; FIG. 1b shows the perspective view of the annulus 115.

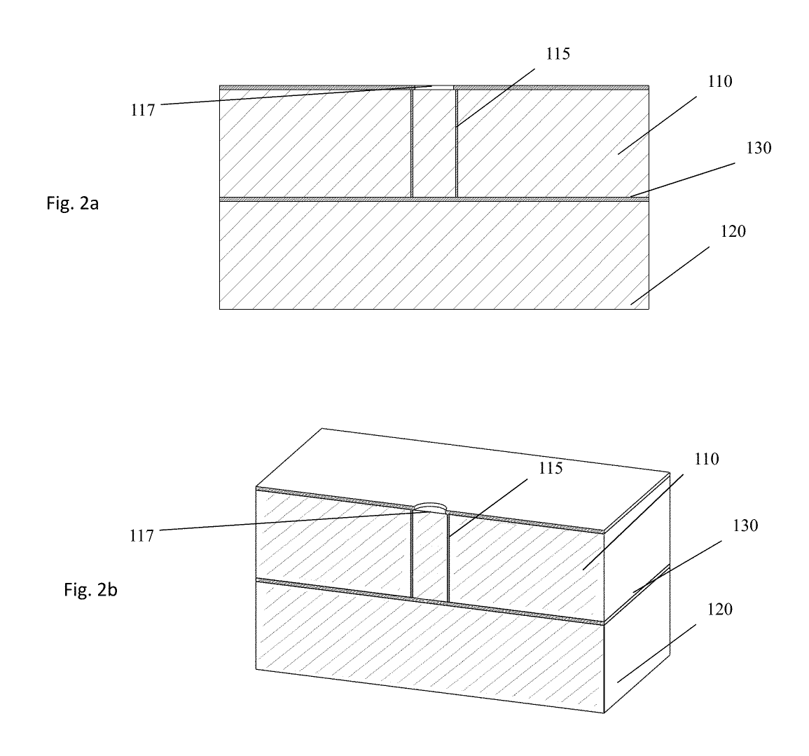

After formation of the annulus 115, the SOI substrate 100 may be oxidized. In one embodiment, a thermal oxide 117 of SiO₂ is grown on all of the exposed silicon surfaces. As is well known in the art, this thermal oxide may be formed by heating the substrate 100 in a furnace at 800-1200C for a period of several days. Accordingly, the thermal oxide may be formed over the silicon substrate, on the surfaces of the substrate and within the annulus, to a thickness of several microns, but generally less than 5 microns. These structures are shown in cross section in FIG. 2a.

The oxide may then be removed above the annulus, to expose the top of the silicon post as shown most clearly in the perspective drawing of FIG. 2b. The oxide removal may be accomplished by etching through a photomask, as is known in the art. A wet or dry chemical etch may be effective in removing the oxide from the patterned surface.

The condition of substrate 100 is now as shown in FIG. 2b. A post of silicon 115 is surrounded by an oxide wall 117, and exposed and bare on top.

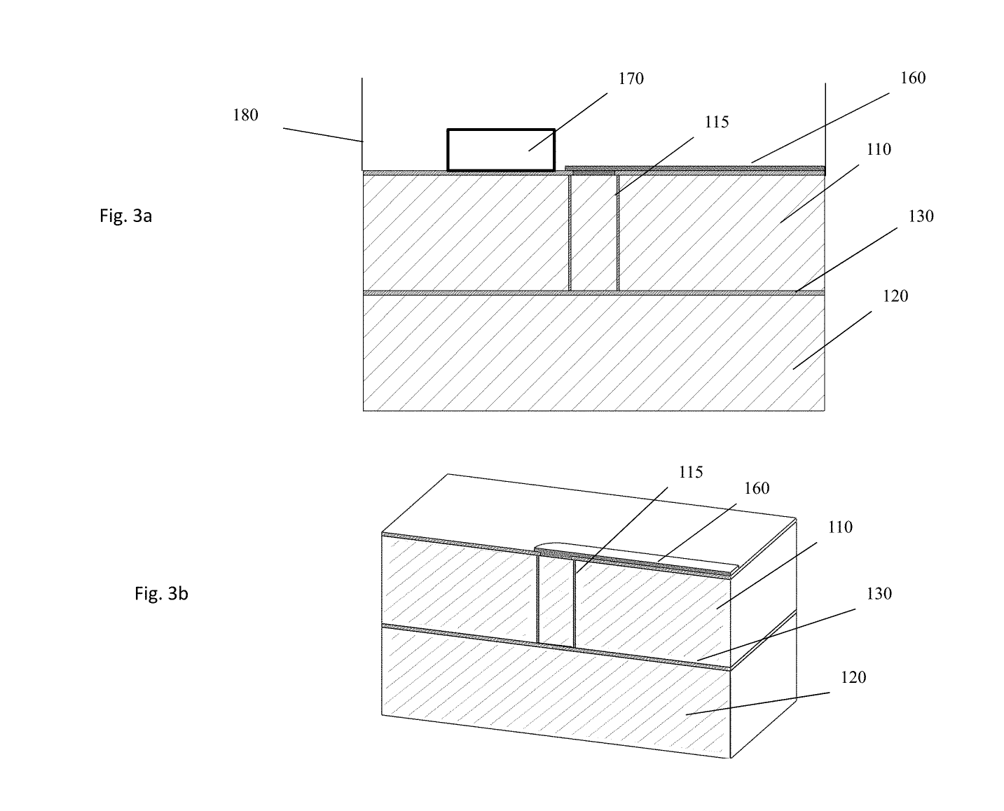

The next step, illustrated in FIGS. 3a and 3b, may be the formation of an electrical pattern 160 on the first side of the SOI substrate 100. The metal pattern may be deposited by sputtering through a lithographic mask, or sputtering and then patterning and etching the metal to create the desired pattern. The deposited metal layer 160 may be, for example, copper (Cu), gold (Au), aluminum (Al), or a copper alloy. The thickness of the metal layer 160 may be anywhere from 0.5 microns to about 5 microns or thicker. The metal layer 160 may be deposited with an optional adhesion or barrier layer such as titanium (Ti), chrome (Cr) or titanium/tungsten (TiW). The adhesion layer may be for example, about 0.01 microns thick.

Accordingly, in the next step, a metal layer may be formed, wherein forming the metal layer comprises forming an adhesion layer over the front side of the silicon substrate, and forming a pattern layer of metal material over the adhesion layer. If the silicon substrate is an SOI substrate, the metal layer may be formed on the device layer 110. If a unitary silicon substrate, the metal layer may be formed on the first side into which the blind annulus was formed.

Any other front side processing may occur at this step as well. For example, any additional structures, actuators, switches, sensors that will constitute or be included in the device may be fabricated on this first side of the SOI substrate 100 at this point. The structures may be of the MEMS sort or the integrated circuit sort. The structures may be, for example, a CMOS device. Since these structures depend on the application, they are not shown in the figures. However, it should be understood that additional features may be formed on the first side of the SOI susbtrate 100. The additional features are shown generically in FIG. 3a, as reference number 170. Therefore, it should be understood that the additional features 170 may be at least one of a MEMS device, and an integrated circuit device formed on the first side of the silicon substrate 100. Accordingly, the method may include forming an active device on the first side of the silicon substrate, wherein the active device comprises at least one of an integrated circuit, a MEMS device, a switch, a sensor and an actuator.

A design consideration is that the metal layer 160 be formed of sufficient thickness to have sufficient mechanical strength to act as an unsupported membrane. That is, the area directly above metal layer 160 may be an evacuated cavity. Therefore, depending on the dimensions of the structures, the metal layer 160 may be required to span an opening with vacuum on one side and atmosphere on the other. Accordingly, it should preferably be made with a thickness sufficient to withstand this force without rupturing. Accordingly, forming a metal layer over the annulus comprises forming a metal layer using at least one of sputter deposition, evaporation, or plating, and forming the metal layer to a thickness that can withstand a pressure vacuum on one side and atmospheric pressure on the other.

The metal pattern 160 may be used to deliver a signal or a voltage between the first side and the opposite side of the silicon substrate 100. More generally, the TSVs may be used to provide a signal or voltage from the exterior of an enclosed device, to the enclosed device.

A lid wafer 180 may be bonded to the first side of the SOI wafer at this point, encapsulating all the structures formed on the first side. The lid wafer is shown generically as reference number 180 in FIG. 3a. Although for clarity of depiction, structures 170 and 180 are not shown throughout the remaining figures, they should be understood to be optionally there.

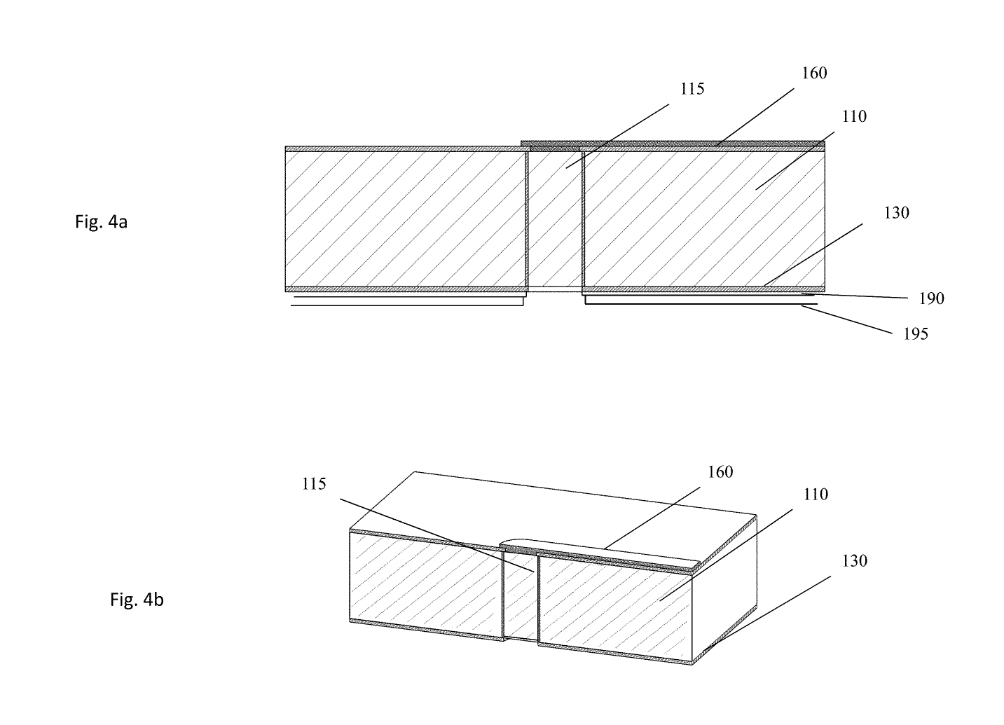

The next step of the process is illustrated in FIGS. 4a and 4b. In this step, the handle layer 120 may be removed from the SOI substrate 100 to expose the buried oxide 130. This step will expose the opposite side of the substrate for further processing, as described below.

The handle layer 120 may be removed by grasping the perimeter of the SOI substrate 100 in a fixture, and submerging the handle layer 120 in an etching bath. It can also be removed by dry etch. It can also be remove by mechanical grinding and polishing.

The buried oxide 130 may be removed in the area beneath the silicon post 115. Because remove of the oxide in this area may require photolithographic masks and thin film processing, it may be convenient to have placed alignment marks or fiducials on the first side of device layer 110 of silicon substrate 100. These alignment marks may be, for example, trenches etched 3-5 microns deep in the first side of the substrate 100. Because these techniques are well known in the art, they are not depicted in detail in the figures. Having now removed the handle layer 120, these alignment marks may be imaged through the substrate, such that the location of the silicon post 115 is known with respect to the alignment marks. Having patterned the lithographic mask appropriately, the oxide layer adjacent to the post 115 may now be removed using standard etching procedures. This step completes the preparation of the opposite side surfaces.

Accordingly, in some embodiments when the silicon substrate is a silicon-on-insulator (SOI) substrate, and the front side of the silicon substrate may be the device layer of the silicon-on-insulator substrate, removing substrate material from the opposite side may comprise removing the handle layer from the silicon-on-insulator substrate. For other substrates such as a unitary silicon substrate, the opposite side silicon may be removed by etching or grinding to the level of the blind annulus that was formed in the first side. For still other embodiments, front side of the silicon substrate may be the handle layer of the silicon-on-insulator substrate, removing substrate material from the opposite side may comprise removing the device layer from the silicon-on-insulator substrate, as will be described further below.

Additional structures may now be added according to standard opposite side processing. These additional structures may include exemplary layers 190 and 195, as illustrated on FIGS. 4a and 4b, which may be, for example, metal patterns which will provide electrical access to the via 115. Accordingly, the metal patterns may be electrical traces, and additional bonding pads may be formed on the opposite side of the silicon substrate, before removing the silicon post which will be described next.

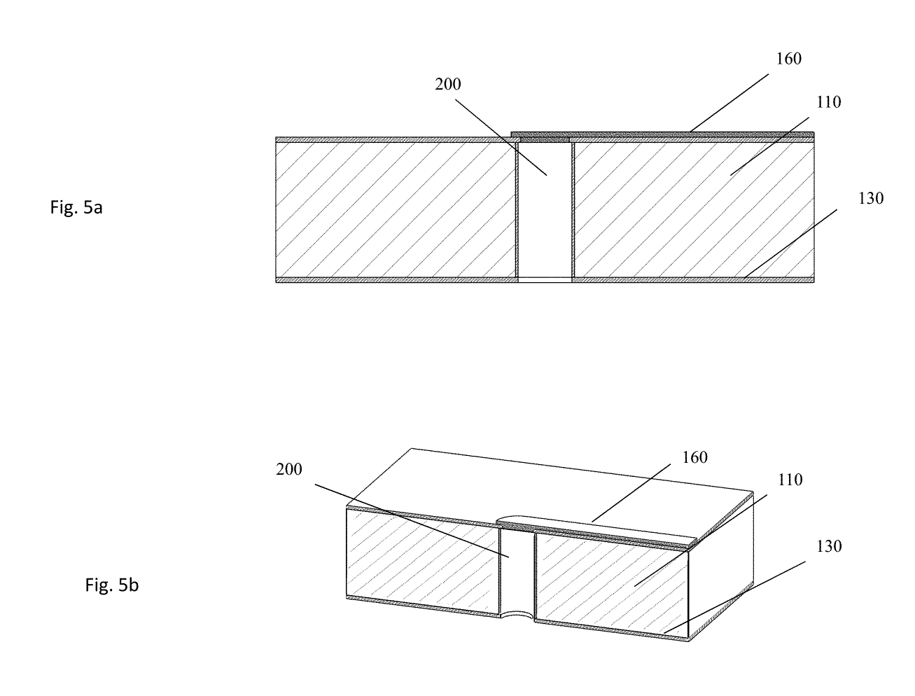

FIGS. 5a and 5b illustrate the next step in the process, which is the removal of the silicon post 115 and its replacement with the metal via. The post 115 may be removed with DRIE for example. The DRIE may use the buried oxide layer 130 existing over most of the surface except the bottom of the silicon post 115 as a hard mask. The DRIE may then remove the material of the silicon post 115, which is now a via void 200. That is, there now remains a cylindrical void 200 in device layer 110.

A seed layer (not shown) may now be deposited conformally in the via void 200. In some cases, this thin layer of conductive material may be adequate for carrying voltage and current from the opposite side of the substrate to the first side. In other embodiments, the seed layer may be used to deposit additional metal material into the via void 200.

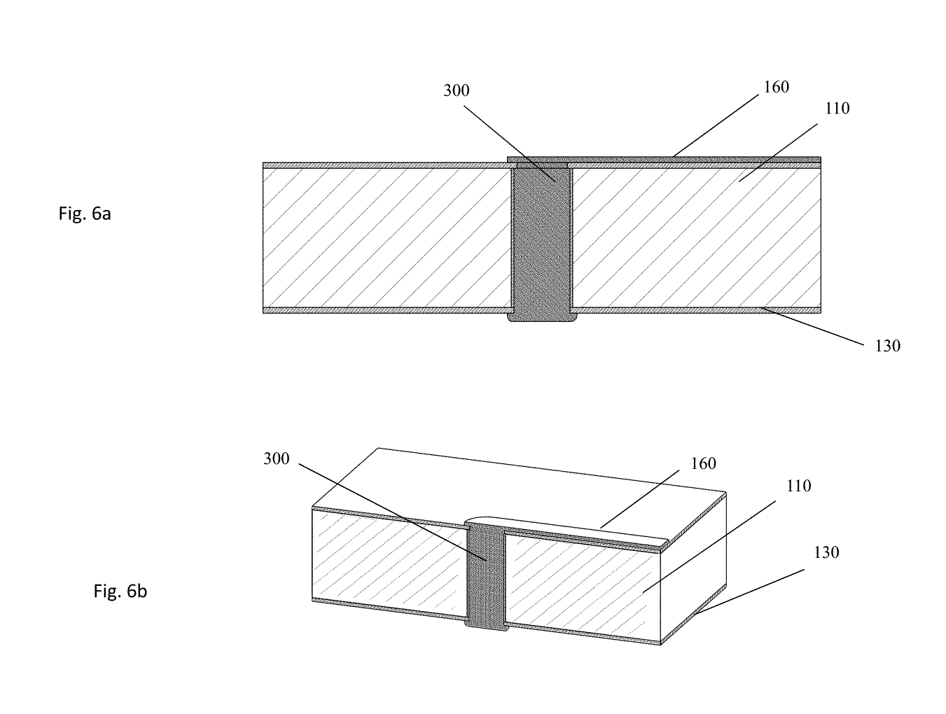

In the embodiment shown in FIG. 6a, the via void 200 is filled by plating metal material 300 into the via void 200. This metal material 300 may be, for example, gold (Au) or copper (Cu). The plated material may be deposited onto the seed layer described above, in addition to an optional adhesion layer or barrier layer. The adhesion layer may be, for example, chromium (Cr) or titanium (Ti). The adhesion, barrier or seed layers may be deposited by sputter, physical vapor deposition (PVD) for example, and may be about 0.1 microns thick. This deposition may then be followed by the formation of a conductive material 300 in the via void 200, as described further below. It should be understood that any barrier layers, seed layers, and/or adhesion layers may be optional, and may depend on the tools being used and the applications being targeted.

With the seed, barrier or adhesion layers in place, the void may be filled with a conductive material 300. If the material is plated, the plating process may slightly overfill the via void 200, such that material is deposited beyond the opposite side surface of the substrate. The extra material may be removed by chemical mechanical polishing (CMP) to obtain a flush, planar surface. The finished condition of the substrate, now with vias extending through the thickness of the substrate, is shown in cross section in FIG. 6a and in perspective view in FIG. 6b. Accordingly, in one embodiment, depositing metal in the via hole may include forming a seed layer in the via hole and filling the via hole by plating metal onto the seed layer to fill the via hole. Depositing metal 300 in the via hole may comprise plating at least one of gold, copper, an alloy of copper and aluminum into the via hole, and removing any excess plated material with chemical mechanical polishing.

In another embodiment, the via hole may be filled with a solder material. A nozzle may be brought into the position of the via void 200 and a quantity of solder dispensed from the nozzle, as performed in bump bonding processes. Upon heating, the solder material may liquefy and flow into the via void 200. Upon contact with the relatively cool substrate surface, the solder material may freeze or solidify, filling the via void 200 and forming the conductive material of the through substrate via 300. Examples of appropriate solder materials may include:
SnAgCu
SnAg
PbSn 95/5, PbSn 90/10
AuSn 80/20
InSn
SnBi

Details as to the various processing steps may be similar or identical to those described previously with respect to the SOI embodiment illustrated by FIGS. 1-6b.

In one particular embodiment, a through substrate via is disposed at the bottom of a trench formed in the substrate. The substrate may be, but is not necessarily, an SOI substrate with a device layer, and buried oxide layer, and a handle layer. More generally, however, the method may use a composite substrate having a first substrate layer 510, a buried etch stop layer 530 and a second substrate layer 540. The “first surface” of the composite substrate may be the outer surface of the first layer 510 and the “second surface” may be the outer surface of the second layer 540. The process will be described with respect to an SOI embodiment, but it should be understood that this is exemplary only.

The method for forming this structure is generally as follows:
1) Form a hole or annulus on the first side
2) Deposit an insulator
3) Deposit a metallic material to make conductive vias
4) Partially remove the second side
5) Form insulator on first side
6) Form the trenches on second side
7) Form insulator on second side
8) Pattern insulator on second side
9) Pattern conductor on second side

These process steps are shown in FIGS. 7-14, and described below. The process begins with a multilayer substrate, having a first silicon layer 510, a second silicon layer 540, and an insulating etch stop layer 530 between the first layer 510 and the second layer 540. The first layer may be, but is not necessarily, a device layer of an SOI substrate, and the second layer may be, but is not necessarily, the handle layer of an SOI substrate

FIG. 7a shows a first step in which at least one annulus or hole 515 is formed in first substrate layer 510 in the substrate. The feature may be formed using DRIE, and the first annulus 515 may extend from the lower surface to the etch stop layer for a short via. For the longer via 515′, the hole may extend through the etch stop layer 530 and end in a blind hole, or a through hole through the entire thickness of the substrate. (In general, reference number xxx refers to features that end at the etch stop layer 530, whereas reference number xxx′ refers to features that extend beyond the rtch stop layer and into the second substrate layer 540). The shorter via 515 will eventually end at the bottom of the trench, whereas the longer hole 515′ may extend through the entire substrate. The holes 515, 515′ define the first side of the substrate in the first layer 510.

FIG. 7b is similar to FIG. 7a, but pertains to the case wherein the via is made of a non-silicon conductive material. In this case, the feature 525 is a hole rather than an annulus, as shown in FIG. 7b.

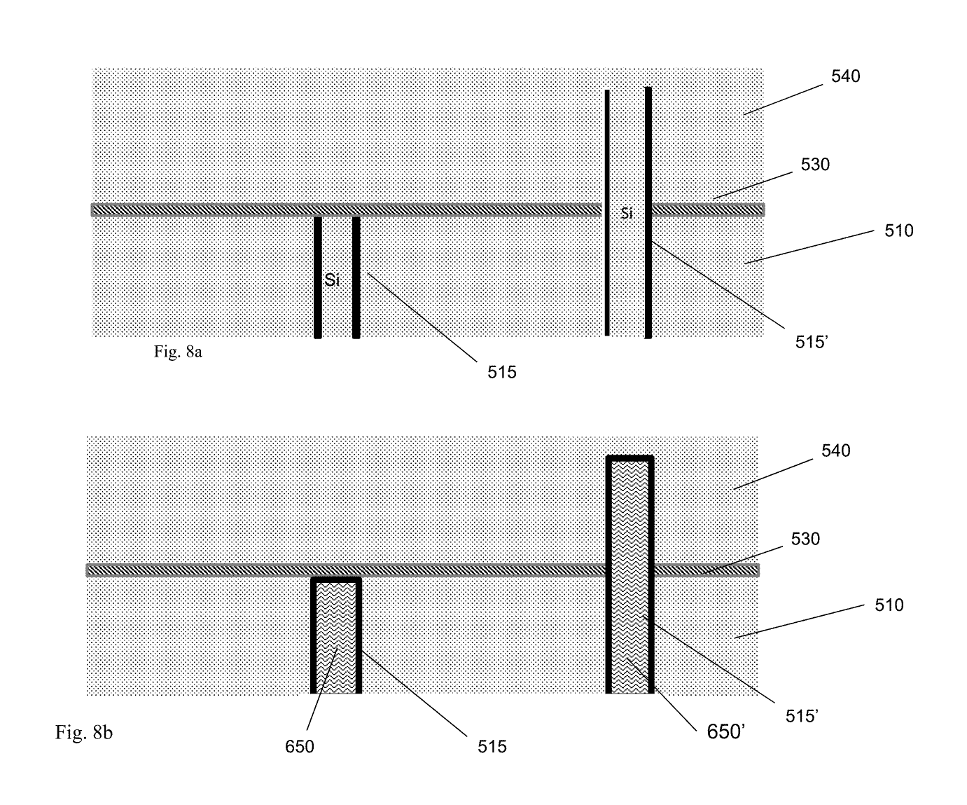

FIGS. 8a and 8b show a second step of the process. In the second step, the hole/annulus 515 and 515′ may be filled with and insulator. The insulator may be a ceramic or a polymer forced into the holes and cured, or it may be an oxide grown or deposited on the surfaces, including on the walls of the holes. Accordingly, the insulator may be a curable, organic material.

FIG. 8b is similar to FIG. 8a, but pertains to the case wherein the via is made of a non-silicon conductive material. In this case, a preferred conductive material may then be deposited in the holes of FIG. 7b. For copper, for example, the copper may be plated onto a seed layer formed over the insulating layer. If silicon is acceptable for the via conductive material, the silicon may be in the form of the post left by formation of the annulus. Going forward in this discussion, 515 and 515′ may refer generally to either the hole, or the insulator coated hole, or the conductive material deposited in the insulator-coated holes. In any case, 515 refers to the shorter hole ending at the etch stop layer 530, and 515′ refers to the longer hole penetrating into the second layer of the composite substrate, 540.

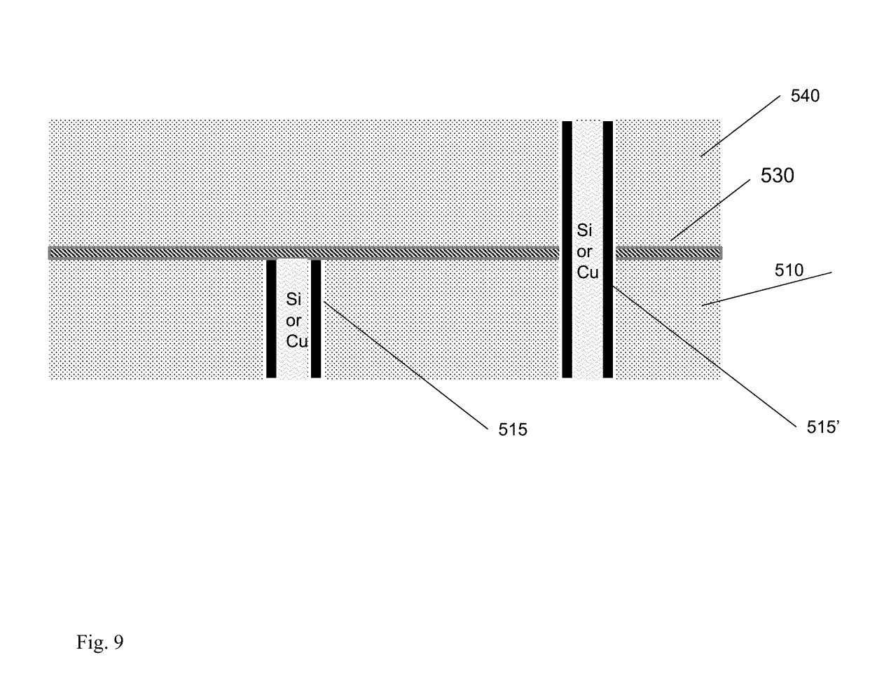

FIG. 9 shows a third step in the process, wherein the obverse, second side of the composite substrate, i.e. the outer surface of the second substrate layer 540, is at least partially removed to reveal blind hole/annulus 515′. The obverse or second side of the substrate may be ground or etched down to reveal the conductive material deposited in the blind holes 515′. The conductive material is now a through substrate via.

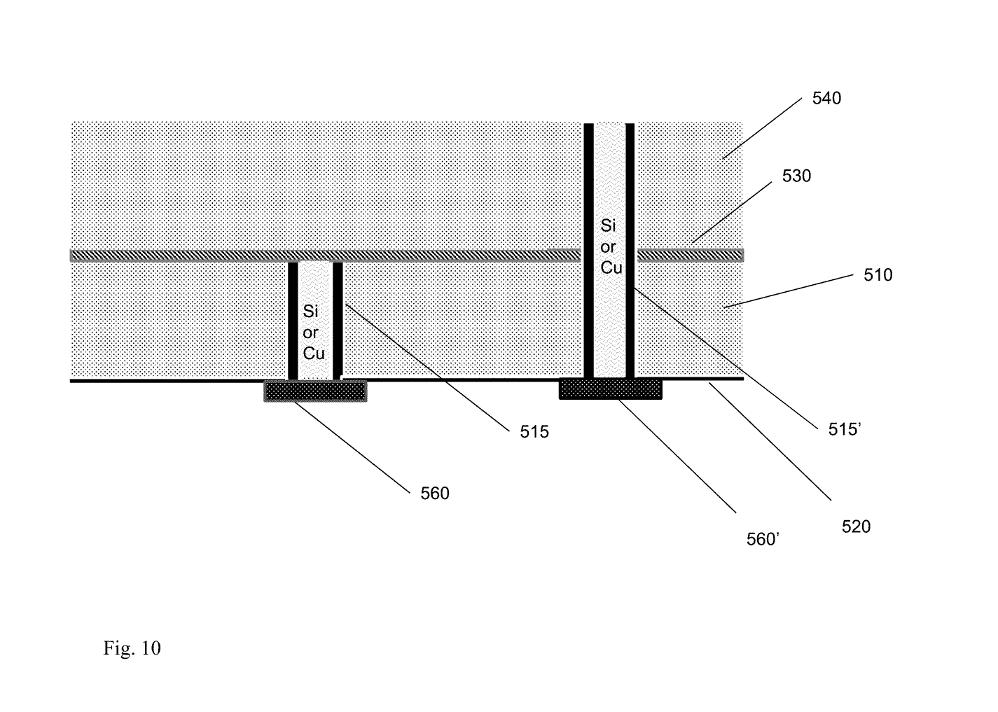

FIG. 10 shows a fourth step in the process, wherein an insulator 520 is grown or deposited on the first side. The insulator 520 may need to be patterned to reveal the conductive material of the through vias 515, 515′. Conductive pads 560, 560′ are then formed over the conductive material 515, 515′, providing electrical access to the via.

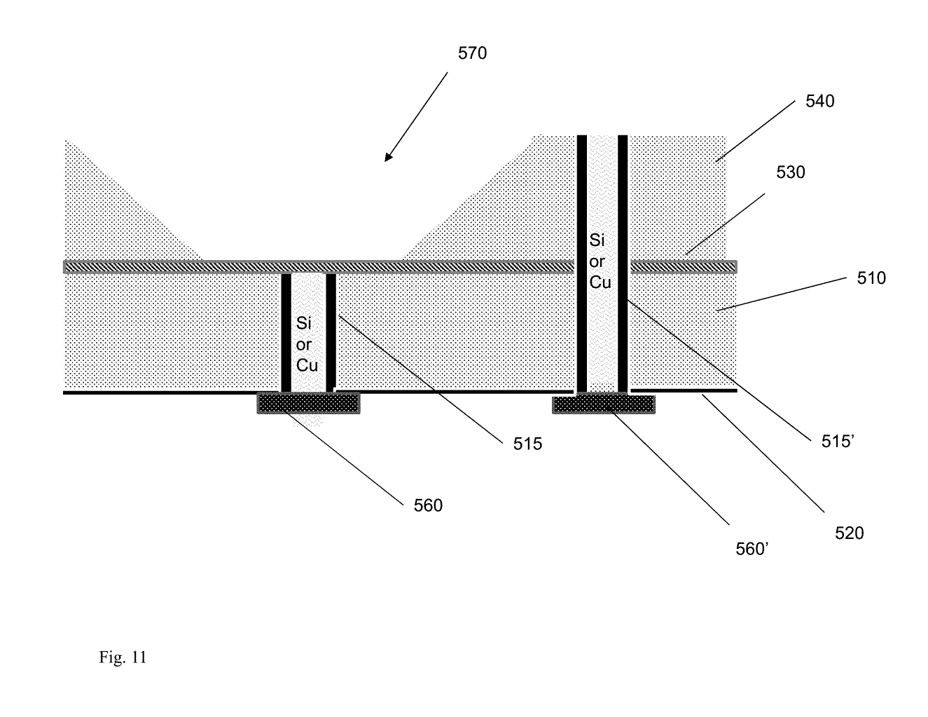

FIG. 11 shows a fifth step in the process. A trench 570 may be formed on the second, obverse side of the substrate in the second layer 540. Since the trench may be etched, the depth may extend to, but not beyond, the etch stop layer 530.

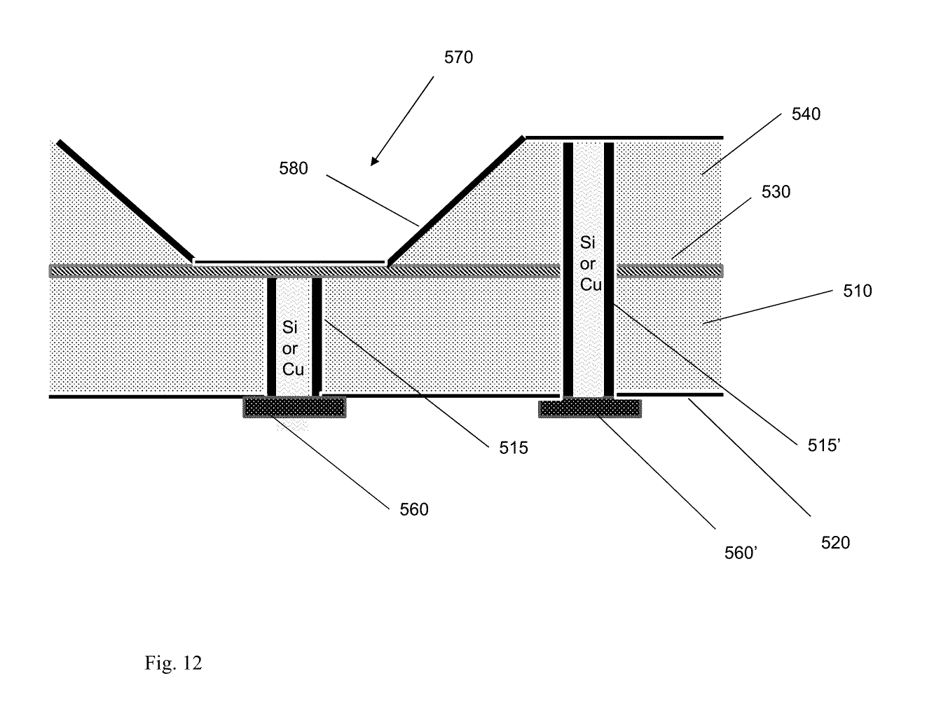

FIG. 12 shows a next step in the process. A second insulator 580, for example an oxide, is formed on the second side, over the top surface of the second layer 540, and down into the trench 570.

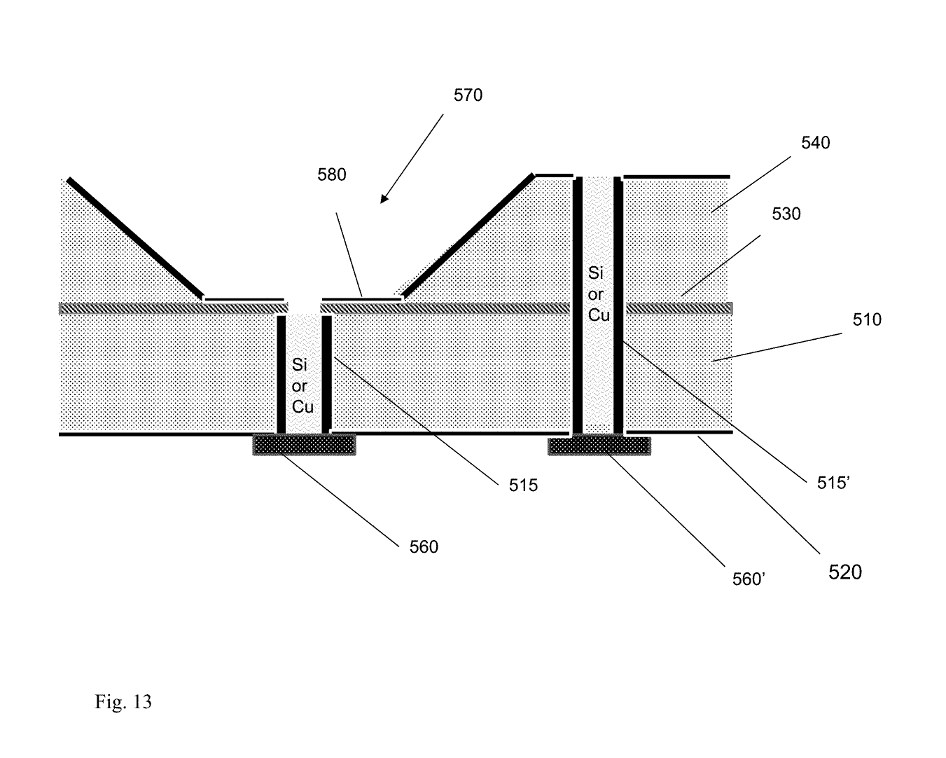

FIG. 13 shows a next step in the process. The second insulator 580 may be patterned to reveal the tops of the conductive material 515, 515′. The etch stop layer over the conductive material is also removed, providing access to the through substrate via.

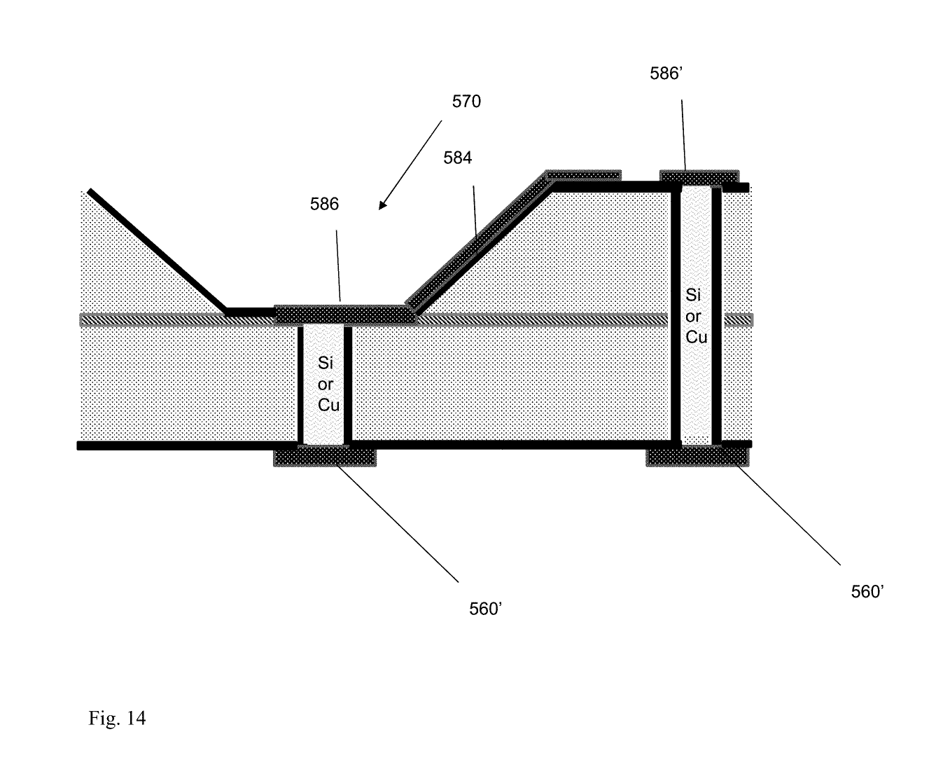

FIG. 14 shows a final step in the process. A conductor 584 may be formed on the second side. Metal pads 586 may patterned in the conductor 584 over the exposed tops of the conductive material 515 inside the vias. Patterning of the conductor 584 may also form pad 586′ and may isolate via 515 from via 515′ as shown in FIG. 14. These metal pads 586, 586′, 560, 560′ and conductive material 515, 515′ now form a conductive path through the thickness of the substrate. Accordingly, these structures form the through substrate via.

FIGS. 15-18 show the finished products of the process described above with respect to FIGS. 7-14.

FIG. 15 is a cross sectional diagram of a first embodiment of a through substrate via fabricated according to the method described above. Among the novel features of the device are: A through substrate via 550 of conductive silicon extending from a pad 560 on the first surface to a pad 586 on the top of the etch stop layer 530. A wall of insulating material 515 may isolate the via 550 from the rest of the surrounding substrate 510. A first metal pad 560 may be disposed on the lower first surface providing electrical access, and a second metal pad 586 may be disposed on the second top surface. The top surface of the via 515 may be located at the bottom of the trench 570, as shown.

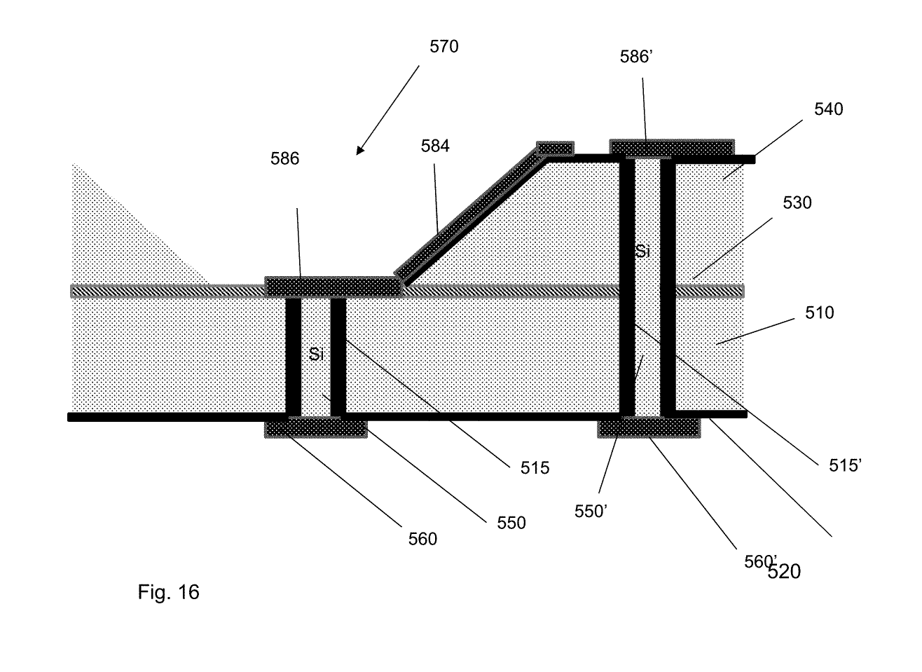

FIG. 16 is a cross sectional diagram of a second embodiment of a through substrate via fabricated according to the method described above. This embodiment may include two vias: a shorter TSV 515 that extends only up to the trench 570, and a second, longer via 515′ extending through the entire thickness of the composite substrate. Among the novel features of the device are: A through substrate via 550 of conductive silicon extending from a pad 560 on the first surface to a pad 586 on the top of the etch stop layer 530. A wall of insulating material 515 may isolate the via 550 from the rest of the surrounding substrate 510. A first metal pad 560 may be disposed on the lower first surface providing electrical access, and a second metal pad 586 may be disposed on the second top surface. The top surface of the via 515 may be located at the bottom of the trench 570.

This embodiment may also have a second, longer via 550′ A through substrate via 550′ of conductive silicon extending from another pad 560′ on the first surface to a second pad 586′ on the top surface, through the entire composite wafer thickness. A wall of insulating material 515′ may isolate the via 550′ from the rest of the surrounding substrate 510, and from via 550. A first metal pad 560′ may be disposed on the lower first surface providing electrical access, and the second metal pad 586′ may be disposed on the second top surface. The top surface of the via 515′ may be located at the top of the second portion 540 of the composite wafer.

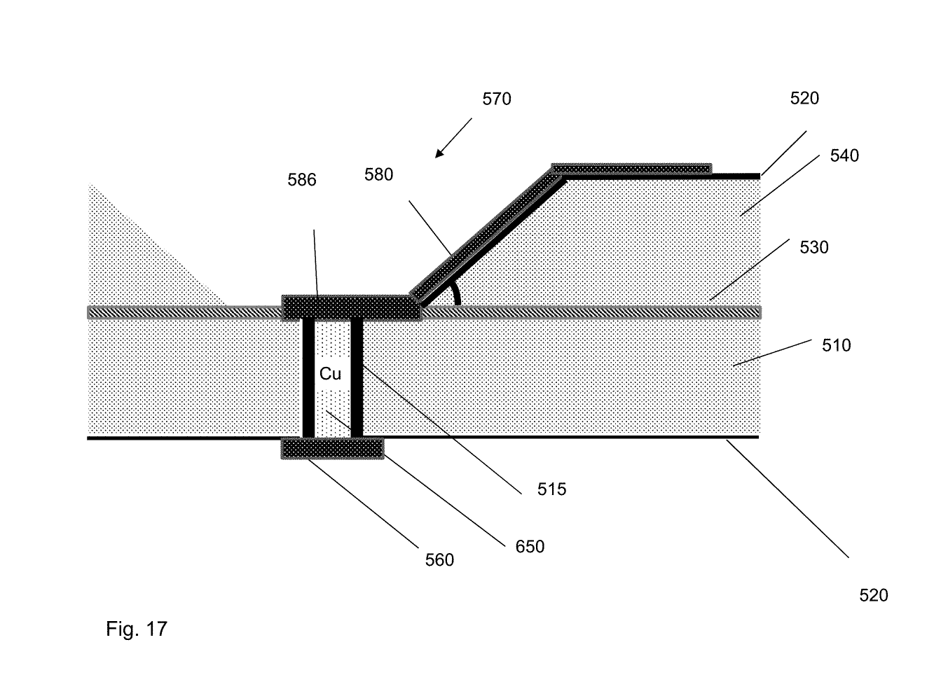

FIG. 17 is a cross sectional diagram of a third embodiment of a through substrate via fabricated according to the method described above. Among the novel features of the device are: A through substrate via 650 of conductive material extending from the first surface to the top of the etch stop layer 530. The conductive material 650 may be deposited in a hole that was DRIE into the back (first) side of the first substrate material 510. The metallic material 650 may be plated onto a seed layer (not shown in FIG. 17). The metallic conductive material may be, for example, gold, silver, zinc, aluminum, copper, tungsten or an alloy thereof.

A wall of insulating material 515 may isolate the via 650 from the rest of the surrounding substrate 510. A first metal pad 560 may be disposed on the lower first surface providing electrical access, and a second metal pad 586 may be disposed at the bottom of the trench 570. Accordingly, the top surface of the via 515, and thus pad 586, may be located at the bottom of the trench 570. In contrast to the first embodiment, the conductive via material 650 may be generally metallic rather than specifically silicon. Suitable metal materials may include gold, aluminum, zinc, silver, and alloys thereof, for example.

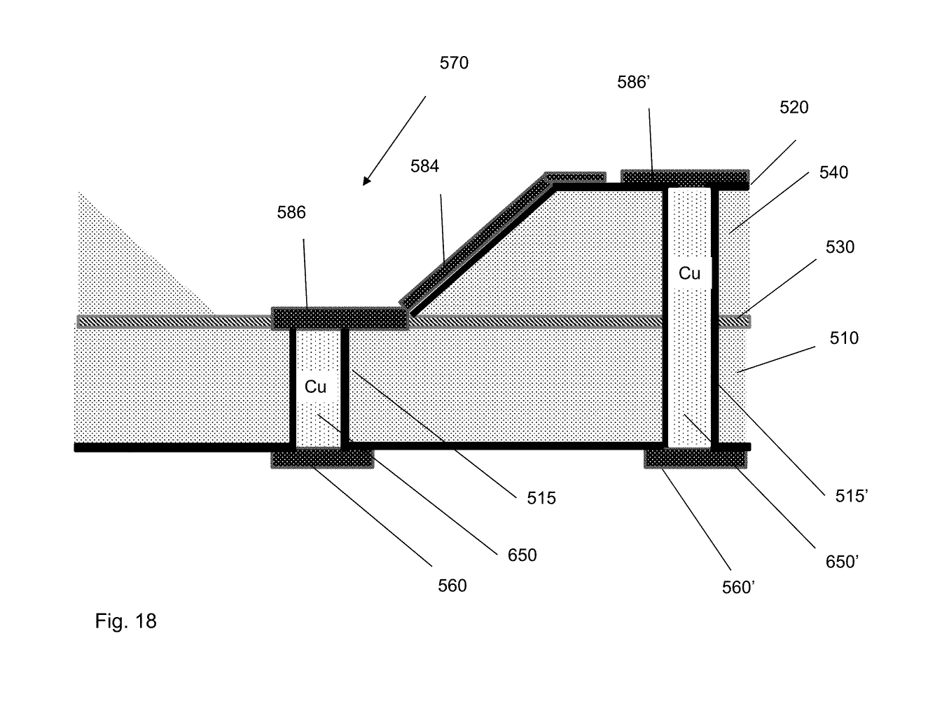

FIG. 18 is a cross sectional diagram of a fourth embodiment of a through substrate via fabricated according to the method described above. This embodiment may have a shorter TSV 650 that extends only up to the trench 570, and a second, longer TSV 650′ extending through the entire thickness of the substrate. Among the novel features of the device are: A through substrate via 650 of conductive material may extend from the first surface to the top of the etch stop layer 530. A wall of insulating material 515 may isolate the via 550 from the rest of the surrounding substrate 510. A first metal pad 560 may be disposed on the lower first surface providing electrical access, and a second metal pad 586 may be disposed on the second top surface. The top surface of the via 515 may be located at the bottom of the trench 570.

This embodiment may have a second, longer via TSV 650′ also comprising a metallic material. A through substrate via 650′ of conductive metal may extend from the first surface to the top, through the entire wafer thickness. A wall of insulating material 515′ may isolate the via 650 from the rest of the surrounding substrate 510. A first metal pad 560′ may be disposed on the lower first surface providing electrical access, and a second metal pad 586′ may be disposed on the second top surface. The top surface of the via 515′ and thus second pad 586′ may be located at the top of the second portion 540 of the composite wafer. Thus the second via 515′ may extend through the entire thickness of the composite substrate.

FIG. 20a is a plan view of the embodiment wherein the via material 515, 515′ is silicon. In FIG. 20, the composite substrate may be an SOI water with layers 540 and 510, wherein an annulus 515 is formed in the substrate layer 510. The annulus 515 may be a blind annulus such that the void ends at a point within the substrate as shown in the cross section of FIG. 19b. After formation of the insulator as described above, FIG. 19c shows the embodiment after removal of the backside material to reveal the conductive material in the via 515.

In FIG. 20a, a plan view of the embodiment wherein the conductive material in the vias 515, 515′ is an insulating material. In the next stage, an insulating material is disposed within the annular void. This insulator may be, for example, a polymer which may be forced into the annulus with pressure. The viscous liquid may be cured while in the void to for the insulating layer 515. After curing of the insulator, the backside of the substrate 540 may be ground down, etched, or otherwise removed, as shown in FIG. 20b. The removal of material may expose the conductive material in the via. The removal process is shown schematically in FIG. 20c.

FIG. 21 is an exemplary flowchart of a method for forming a through substrate via in a trench. The method begins in step S10. In step S20, the hole is formed in composite substrate. In step S30, the annulus is filled with an insulator(s). In step S40, the insulator is formed and the metal layers on the first side of substrate. In step S50, the trench is etched into 2nd side of substrate over filled annulus. In step S60, the insulator layer is deposited and patterned on top of substrate, sidewall and into trench. In step S70, the metal layer is deposited and patterned on top of substrate, sidewall and into trench. The method ends in step S80. This method may form the silicon through substrate vias shown in FIGS. 15 and 16.

FIG. 22 is an exemplary flowchart of a second method for forming a through substrate via in a trench, wherein the material of the via is a non-silcon conductive material, such as copper. The method begins in step S100. In step S200, the hole is formed in composite substrate. In step S300, an insulator and a diffusion barrier is formed on the walls of the hole. In step S400, a conductor is deposited into the holes. In step S350 a conductive material is deposited into the holes. In step S400, an insulator and metal layers are formed on the first side of substrate. In step S500, the trench is etched into 2nd side of substrate over filled annulus. In step S600, the insulator layer is deposited and patterned on top of substrate, sidewall and into trench. In step S70, the metal layer is deposited and patterned on top of substrate, sidewall and into trench. The method ends in step S800. This method may form the metallic through substrate vias shown in FIGS. 17 and 18.

Accordingly, a through substrate via in a composite substrate has been described. The composite substrate may have an embedded insulating etch stop layer sandwiched between a first and a second substrate layers. The through substrate via may be formed in the composite substrate, and the via may include at least one hole formed in the first substrate layer down to the embedded insulating etch stop layer, an insulator formed onto the walls of the at least one hole, a conductive material disposed in the at least one hole, a trench etched into the second substrate layer on the obverse side of the composite substrate through the second substrate material and through the embedded insulating etch stop layer, directly opposite the at least one hole, and a first metal pad formed over the at least one hole and at the bottom of the trench.

The at least one hole may be an annulus, and the annulus may not penetrate through a thickness of the composite substrate. The conductive material may comprise at least one of gold, silver, zinc, aluminum, tungsten and copper, silicon, and alloys thereof, disposed in the at least one hole. The via may include an adhesion layer formed beneath the metal pad, which adheres the metal pad to the bottom of the trench and to the conductive material. A device or a structure may also be disposed in the trench, and coupled electrically to the metal pad and conductive material.

For the through substrate via having at least one hole, the hole may be an annulus, and annulus may not penetrate through a thickness of the composite substrate. The trench may have a sloping sidewall, and this sloping sidewall may have a patterned conductor deposited thereon, wherein the conductor also forms the first metal pad. The via may further comprise an additional bonding pads formed on the obverse side of the composite substrate from the first metal pad.

The composite substrate may be a silicon-on-insulator substrate, and the hole may be formed to a depth that is a thickness of the device layer of the silicon-on-insulator substrate, such that the hole extends completely through the device layer. The trench may have a width of about 20-3000 microns and a depth of about 10-500 microns, and the hole has a diameter of about 20-150 microns.

A method for forming a through substrate vias is also described. The method may be for forming a through substrate via in a composite substrate, wherein the composite substrate had an embedded insulating etch stop layer sandwiched between a first and a second substrate layers. The method may include forming at least one hole in the first substrate layer down to the embedded insulating etch stop layer, disposing an insulator onto the walls of the at least one hole, disposing a conductive material in the at least one hole, etching a trench into the second substrate layer on the obverse side of the composite substrate through the second substrate material and through the embedded insulating etch stop layer, directly opposite the at least one hole, and forming a metal material as a pad over the at least one hole and at the bottom of the trench.

Within the method, the at least one hole may be an annulus, and the annulus may not penetrate through a thickness of the composite substrate. Within the method, depositing a conductive material may include depositing a metal in the at least one hole. The composite substrate may be a silicon-on-insulator substrate, wherein the first side of the composite substrate is a device layer of the silicon-on-insulator substrate, and the opposite side is a handle layer, and wherein removing the composite substrate material from the opposite side comprises removing a handle layer from the silicon-on-insulator substrate.

Within the method, disposing an insulator may include disposing a quantity of an organic material over the annulus, forcing the organic material into the annulus, and curing the organic material. Disposing an insulator may comprise disposing an inorganic material as insulator. The method may include forming a silicon dioxide, silicon nitride, aluminum oxide layer or a combination of the several materials in the annulus.

Forming the annulus may comprise forming the annulus to a depth that is less than the thickness of the composite substrate material, such that the annulus is a blind annulus.

When the composite substrate is a silicon-on-insulator substrate, forming the annulus may comprise forming the annulus to a depth that is a thickness of a device layer of the silicon-on-insulator substrate, such that the annulus extends completely through the device layer. Depositing the metal material in the via hole may comprise depositing at least one of gold, silver, zinc, aluminum, copper, or an alloy thereof, into the via hole, and removing any excess deposited material with chemical mechanical polishing.

Forming a metal layer over the annulus may comprise forming a metal layer using at least one of sputter deposition, evaporation, or plating methods, and forming the metal layer to a thickness that can withstand a pressure vacuum on one side and atmospheric pressure on another side of the metal layer.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure.

What is claimed is:

1. A through substrate via in a composite substrate, wherein the composite substrate has an embedded insulating etch stop layer sandwiched between a first and a second substrate layers, comprising:
at least one hole formed in the first substrate layer down to the embedded insulating etch stop layer;
an insulator formed onto the walls of the at least one hole;
a conductive material disposed in the at least one hole;
a trench etched into the second substrate layer on the obverse side of the composite substrate through the second substrate material and through the embedded insulating etch stop layer, directly opposite the at least one hole; and
a first metal pad formed over the at least one hole and at the bottom of the trench.

2. The through substrate via of claim 1, wherein the at least one hole is an annulus, and the annulus does not penetrate through a thickness of the composite substrate.

3. The through substrate via of claim 1, wherein the conductive material comprises at least one of gold, silver, zinc, aluminum, tungsten and copper, silicon, and alloys thereof, disposed in the at least one hole.

4. The through substrate via of claim 1, further comprising an adhesion layer formed beneath the metal pad, which adheres the metal pad to the bottom of the trench and to the conductive material.

5. The through substrate via of claim 1, further comprising a device or a structure disposed in the trench, and coupled electrically to the metal pad and conductive material.

6. The through substrate via of claim 1, wherein the at least one hole is an annulus, and annulus does not penetrate through a thickness of the composite substrate.

7. The through substrate via of claim 1, wherein the trench has a sloping sidewall, and this sloping sidewall has a patterned conductor deposited thereon, wherein the conductor also forms the first metal pad.

8. The through substrate via of claim 1, further comprising an additional bonding pads formed on the obverse side of the composite substrate from the first metal pad.

9. The through substrate via of claim 1, wherein the composite substrate is a silicon-on-insulator substrate, and the hole is formed to a depth that is a thickness of the device layer of the silicon-on-insulator substrate, such that the hole extends completely through the device layer.

10. The through substrate via of claim 1, wherein the trench has a width of about 20-3000 microns and a depth of about 10-500 microns, and the hole has a diameter of about 20-150 microns.

11. A method for forming a through substrate via in a composite substrate, wherein the composite substrate had an embedded insulating etch stop layer sandwiched between a first and a second substrate layers, comprising:
forming at least one hole in the first substrate layer down to the embedded insulating etch stop layer;
disposing an insulator onto the walls of the at least one hole;
disposing a conductive material in the at least one hole;
etching a trench into the second substrate layer on the obverse side of the composite substrate through the second substrate material and through the embedded insulating etch stop layer, directly opposite the at least one hole; and
forming a metal material as a pad over the at least one hole and at the bottom of the trench.

12. The method of claim 11, wherein the at least one hole is an annulus, and annulus does not penetrate through a thickness of the composite substrate.

13. The method of claim 11, wherein depositing a conductive material comprises:
depositing a metal in the at least one hole.

14. The method of claim 11, wherein the composite substrate is a silicon-on-insulator substrate, wherein the first side of the composite substrate is a device layer of the silicon-on-insulator substrate, and the opposite side is a handle layer, and wherein removing the composite substrate material from the opposite side comprises removing a handle layer from the silicon-on-insulator substrate.

15. The method of claim 11, wherein disposing an insulator comprises:
disposing a quantity of an organic material over the annulus;
forcing the organic material into the annulus; and
curing the organic material.

16. The method of claim 11, wherein disposing an insulator comprises disposing an inorganic material as insulator comprises:
forming a silicon dioxide, silicon nitride, aluminum oxide layer or a combination of the several materials in the annulus.

17. The method of claim 11, wherein forming the annulus comprises forming the annulus to a depth that is less than the thickness of the composite substrate material, such that the annulus is a blind annulus.

18. The method of claim 11, wherein the composite substrate is a silicon-on-insulator substrate, and wherein forming the annulus comprises forming the annulus to a depth that is a thickness of a device layer of the silicon-on-insulator substrate, such that the annulus extends completely through the device layer.

19. The method of claim 11, wherein depositing the metal material in the via hole comprises depositing at least one of gold, silver, zinc, aluminum, copper, or an alloy thereof, into the via hole, and removing any excess deposited material with chemical mechanical polishing.

20. The method of claim 1, wherein forming a metal layer over the annulus comprises forming a metal layer using at least one of sputter deposition, evaporation, or plating methods, and forming the metal layer to a thickness that can withstand a pressure vacuum on one side and atmospheric pressure on another side of the metal layer.
